(19) United States
(12) Patent Application Publication
(10) Pub. No.: US 2002/0111027 A1
(43) Pub. Date: Aug. 15, 2002

(54) Polishing compositions for noble metals

(76) Inventors: Vikas Sachan, Hockessin, DE (US); Heinz F. Reinhardt, Chadds Ford, PA (US); Terence M. Thomas, Newark, DE (US)

Correspondence Address: Gerald K. Kita, Rodel Holdings, Inc., Suite 1300, 1105 North Market Street, Wilmington, DE, 19899, US

(21) Appl. No.: 09/734,087

(22) Filed: Dec. 11, 2000

Related U.S. Application Data
(60) Provisional application No. 60/171,553, filed on Dec. 22, 1999.
(60) Provisional application No. 60/170,612, filed on Dec. 14, 1999.

(51) Int. Cl. H01L 21/302

(52) U.S. Cl. 438/692

(57) ABSTRACT

The polishing composition of this invention is useful for chemical mechanical polishing of substrates containing noble metals such as platinum and contains sulfur-containing compounds at about 0.1% to 50% by weight of the polishing composition, abrasive particles at about 0.5% to about 55% by weight of the polishing composition and water-soluble organic additives up to about 10% by weight of the polishing composition. The abrasive particles are selected from the group consisting of alumina, ceria, silica, diamond, germania, zirconia, silicon carbide, boron nitride, boron carbide or mixtures thereof. The organic additives improve dispersion of the abrasive particles and also enhance metal removal rates and selectivity for metal removal by stabilizing the pH of the polishing composition and suppressing the dielectric removal rate.

This utility application claims the benefit of U.S. Provisional Patent Application No. 60/170,612 filed on Dec. 14, 1999 and U.S. Provisional Patent Application No. 60/171,553 filed on Dec. 22, 1999.

The present invention is directed to a polishing composition or slurry for polishing a semiconductor substrate. It is known from Matsumoto et al, U.S. Pat. No. 5,492,855, issued Feb. 20, 1996, that sulfur-containing gases can be used for dry etching of platinum wherein the dry etching speed is enhanced by the formation of a platinum-sulfur compound.

According to the invention, a ligand-containing compound is present in an aqueous polishing composition for chemical-mechanical polishing of a semiconductor substrate with a noble metal layer, a barrier layer, and a dielectric layer. The ligand present in the ligand-containing compound forms a complex with the noble metal, with the the complex having a stability constant in a range of about 5 to about 100.

Embodiments of the invention will now be described by way of example with reference to the accompanying drawings.

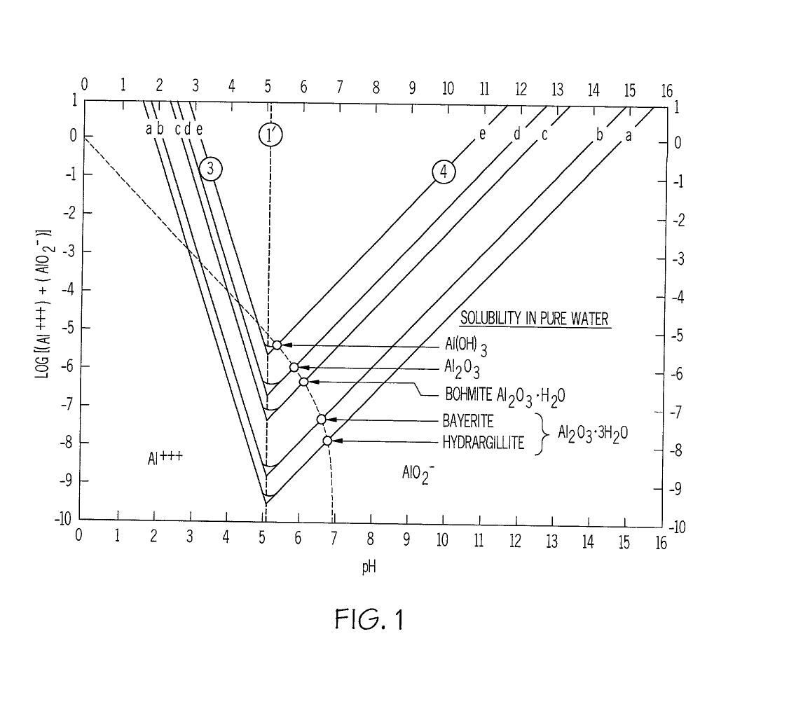

FIG. 1 is a solubility diagram for solid alumina.

While the first applications of known Chemical Mechanical Polishing (CMP) technology were for polishing dielectric films (i.e., SiO₂), CMP has since been applied to polishing metals such as tungsten, copper and aluminum, typically used for interconnects in integrated circuits. In comparison, CMP for noble metals is less developed. The use of noble metals in semiconductors is gaining more interest since noble metals are used as electrodes and barrier materials in Gigabit DRAMs (dynamic random access memory) and FeRAMs (ferroelectric random access memory). Most metal structures contain three different films or layers: a conductive metal layer (e.g., copper, tungsten or platinum), a barrier or liner (e.g. titanium or tantalum alloy) layer between the conductive metal layer and the adjacent dielectric layer, and a dielectric layer (e.g., silicon oxide or silicon dioxide derived from tetraethyl orthosilicate). Integrated circuits are constructed by depositing successive layers of materials (metal, barrier and dielectric layers) on a wafer made of silicon. After each layer is deposited, the layer is etched to create circuitry features on the semiconductor substrate that act as components of integrated circuits. Due to miniaturization of lines and features in the device circuitry, it is extremely difficult to achieve the correct depth of focus and establish an optimized process for photolithography that will compensate for within-die and die-to-die effects associated with non-planar surfaces. Furthermore, as a series of layers are sequentially deposited and etched, the outermost surface of the substrate, becomes increasingly non-planar. Nonplanar surfaces on the wafer result in defects in subsequent circuit layers leading to flawed circuitry. It is thus desirable to have a planar surface on each of the successive layers.

The “damascene” process is employed for forming interconnect lines and vias for multi-layer metal structures that provide the “wiring” of an integrated circuit. The damascene technique involves etching a trench in a planar dielectric (insulator) layer and filling the trench with a metal such as aluminum, copper, or tungsten. A technique called “dual-damascene” adds etched vias for providing contact to the lower level as the damascene structure is filled. When copper is used as the filling, typically a layer of another material is first deposited to line the trenches and vias to prevent the migration of copper ions into the dielectric layer. This migration barrier or barrier layer typically comprises tantalum, tantalum nitride, titanium and/or titanium nitride. In addition to the migration barrier, a conductive seed layer of interconnect metal and/or other metals are applied to serve as a good site for electroless or electrolytic plating. More details are found in “Making the Move to Dual Damascene Processing,” Semiconductor International, August 1997.

Capacitors in integrated circuits are fabricated from polysilicon and metal bonded to polysilicon structures. Typically, the integrated circuit has a foundation dielectric, a first (bottom) and a second (top) electrode with dielectric therebetween. The noble metal or alloy thereof is used for the top and the bottom electrode. In an embodiment, a capacitor in an integrated circuit can be substantially planar. Further details about the structure of capacitors in integrated circuits are found in U.S. Pat. No. 6,040,0616. In one embodiment, the polishing composition of this invention finds application in CMP for the manufacture of planar capacitors in integrated circuits or capacitors with a buried barrier architecture.

In a typical CMP process, for example, if the entire planarization step were to take place in one step of polishing, it would be desirable to have high removal rates of material for the metal and barrier layers, while having low removal rates for the dielectric layer. The ratio of metal removal rate to dielectric removal rate is termed the metal selectivity ratio. To make the CMP process effective for metal removal, it is desirable to keep this ratio as high as possible. The polishing composition according to this invention yields substantially planar polished surfaces with a root mean square surface roughness, RMS, values less than 10 Angstroms and minimal defects. It is common practice to use a single number (an “RMS” number) to characterize surface roughness. RMS is the root mean square deviation of the polished substrate surface from the average amplitude/height of the substrate surface features.

The present invention is directed to a polishing composition or slurry for polishing a semiconductor substrate comprising noble metals (for e.g. platinum), and/or noble metal alloys, provided as a film or layer on the semiconductor substrate, an associated barrier layer (for e.g. tantalum, tantalum nitride, titanium and/or titanium nitride), and an associated dielectric layer (for e.g. thermal oxide or silicon dioxide derived from tetraethyl orthosilicate (TEOS)) for the manufacture of an integrated circuit. A method for polishing a surface comprising noble metals is also provided. Noble metals as referred to herein include the platinum group elements (iridium, palladium, platinum, osmium, rhodium, and ruthenium), silver, gold, oxides and/or alloys thereof. Polishing composition, as referred to herein, includes abrasive-free polishing compositions and slurries which are polishing compositions containing abrasives. In one embodiment, the invention applies to the manufacture of semiconductor devices with noble metal interconnects. In another embodiment, the invention applies to the manufacture of capacitors in integrated circuits.

In an embodiment, the polishing composition comprises: substantially deionized water with abrasive particles (for e.g. alumina or ceria), along with other additives such as dispersants to keep the abrasive particles in suspension, pH stabilizers (buffers) and other chemicals to enhance the activity of the polishing composition for attaining higher selectivity for removal of the target metal layer (for e.g. platinum). In a specific embodiment, the polishing composition contains water-soluble organic additives up to about 10% by weight of the polishing composition; submicron-sized abrasive particles at about 0.5% to about 55% by weight of the polishing composition; and a ligand-containing compound at about 0.1% to about 50% by weight of the polishing composition wherein the ligand forms a complex with the noble metal, said complex having a stability constant in a range of about 5 to about 100. The water-soluble organic additive contains a moeity such as hydroxy, carboxy, thiol, mercapto, amino and the like and is used to modify the viscosity of the polishing composition; and/or to disperse the abrasive particles in the polishing composition; and/or stabilize the pH of the polishing composition by acting as a pH buffer. Examples of water-soluble organic additives containing carboxy moieties include ammonium hydrogen phthalate and potassium phthalate. An organic compound such as polyvinyl pyrrolidone is used to modify the viscosity of the polishing composition of this invention.

Abrasive particles comprise between 0.5% to 55% by weight of the polishing composition depending on the degree of abrasion required. The abrasive particles can be primary particles having a mean size range of 25 to 500 nm or a mixture of primary particles and agglomerated smaller particles having a mean aggregate size up to 500 nm (primary particle size range of 5 to 100 nm). In an embodiment, the polishing composition has abrasive particles in a mean size range of 5 to 100 nm and the abrasive particles are made of a material having a hardness of about 4 mohs to about 10 mohs. The abrasive particles and agglomerates may be encapsulated while maintaining the hardness, so that the polished substrate has minimal scratches and defects.

Abrasive particles in the polishing composition include but are not limited to alumina, ceria, germania, silica, titania, zirconia diamond, silicon carbide, boron carbide, boron nitride, or combinations thereof. In one embodiment, the polishing composition contains about 99% alpha-alumina. Commercially, alumina is available as alpha-alumina, gamma-alumina and delta-alumina. These phases result from various steps in the dehydration sequence of hydrated aluminum oxide. Alpha-alumina is harder than gamma-alumina and is preferred for the removal of harder substrates such as tungsten and platinum. The hardness of alumina is dependent upon the weight percent of alpha-alumina. Thus, the surface finish of substrates is controlled via the use of alumina with different weight percentages of alpha-alumina. More details about the use of alpha-alumina in slurries is found in U.S. Pat. No. 5,693,239.

In an embodiment, the polishing composition has abrasive particles with a surface area of about 50 to 400 m²/g and a mean aggregate size less than 500 nm. For example, assuming the density of alumina to be 3.96 gm/cc, the theoretical surface area corresponding to a 1 nm diameter spherical particle is about 1,500 m²/gm; the theoretical surface area corresponding to a 10 nm diameter spherical particle is about 150 m²/gm; and the theoretical surface area corresponding to a 500 nm diameter spherical particle is about 3 m^{2/}gm. The actual surface area of the abrasive particles can be measured by the nitrogen adsorption method of S. Brunauer, P. H. Emmet and I. Teller, J. Am. Chemical Society, Volume 60, page 309 (1938) which is commonly referred to as BET measurement. Actual surface area of the abrasive particles is a function of the abrasive particle size distribution (whether monomodal or bimodal) and abrasive particle porosity. The abrasive particle size distribution can be unimodal or bimodal. A unimodal (also referred to as monomodal) particle size distribution has relatively uniformly sized particles whereas a bimodal population contains particles grouped into two distinct populations by particle diameter. Mean particle diameter is typically reported as the particle size for commercially available abrasive materials.

The particles in the polishing composition should be dispersed, and not settle or agglomerate. However, it is understood that depending on the percentages of the primary particles and agglomerated particles, such particles in the polishing composition may settle and require redispersion by mechanical means such as mixing. High shear mixing is employed for the purpose of redispersion.

An organic compound is used as the dispersion agent. The dispersion agent reduces the tendency of the abrasive particles in the polishing composition to adhere to the substrate surface during post-polishing cleaning. In order to further stabilize the slurry against settling, flocculation and agglomeration a variety of other additives such as surfactants, polymeric stabilizers, or other surface active dispersing agents are also used. Many examples of typical surfactants are found in McCutcheon's Emulsifiers and Detergents, North American and International Edition (McCutcheon Division, The MC Publishing Co, April 2000). The fly: surfactant or dispersion agent is added to the polishing composition in an amount to achieve steric stabilization of the abrasive particles.

A stable polishing composition is one in which the zeta potential is greater than +20 millivolts or less than −20 millivolts. Zeta Potential is the potential difference, measured in a liquid, between the shear plane and the bulk of the liquid beyond the limits of the electrical double layer. The zeta potential of the polishing composition is dependent on the pH, type of abrasive (metal oxide) present and the presence of surfactants, salts etc. As the pH is increased, the surface charge increases negatively or positively away from the isoelectric point, until it reaches a maximum value. The isoelectric point being defined as the pH at which the zeta potential is zero. Zeta potential is measured by several standard techniques based such as electrophoresis and electroacoustic spectroscopy (an interaction of electric and acoustic fields). One can apply a sound field and measure the resultant electric field which is referred to as the colloid vibration potential (CVP), or conversely one can apply an electric field and measure the resultant acoustic field which is referred to as the electronic sonic amplitude (ESA). A typical zeta potential measuring tool is similar to the Acoustic and Electroacoustic Spectrometer, Model DT-1200, manufactured by Dispersion Technology, Inc. Mount Kiso, Ky.

Sulfur-containing compounds in an embodiment of the polishing composition enhance the removal of the noble metal present in the substrate being polished. By way of example, an enhanced removal mechanism includes, adsorption of the sulfur-containing compounds onto the noble metal layer in the substrate surface followed by mechanical removal aided by the repetitive motion and friction of the substrate surface against the polishing pad, further aided by an abrasive in the polishing composition. At the interface of the substrate surface and the surrounding polishing composition, the surface noble metal atoms have empty “d” or “s” orbitals that are electron deficient thus enabling complexation with compounds that act as lewis bases or contain lewis-base moieties. Stability constant refers to the equilibrium reaction between the metal cation and the ligand (lewis-base) to form a chelating complex.

Exemplary ligands and corresponding stability constants for some metals are listed in the following table.

| Metal Ion (1) | Ligand | Stability Constant (2) | |
|---|---|---|---|
| Platinum(+2) | Chloride ion | 14 | (25° C., 1.0) |
| | Thiosulfate ion | 43.7 | (25° C., 0.5) |
| Palladium(+2) | Chloride ion | 9.5 | (25° C., 0.5) |
| | Thiosulfate ion | 35 | (25° C., 0.5) |
| Aluminum(+3) | Citrate ion | 11.7 | (25° C., 0.5) |

Notes:
(1) The oxidation state of the metal ion is indicated within parentheses.
(2) The stability constant values are derived from the National Institute of Standards and Technology (NIST) Critically Selected Stability Constants of Metal Complexes, Database Version 5.0, September 1998. The temperature of measurement and the ionic strength are indicated within parentheses.

The high stability constant for the noble metal (for example: platinum) and thiosulfate enhances the dissolution rate of the noble metal from the substrate surface, thereby increasing the noble metal removal rates during CMP.

Either inorganic and/or organic compounds or both containing sulfur are used in an embodiment of the polishing composition to enhance removal of the noble metal present in the substrate. In one embodiment, the polishing composition contains about 0.1% to about 50% by weight of an inorganic or organic sulfur-containing compound.

Examples of an organic “sulfur-containing” compound that are used in the polishing composition of this invention include but are not limited to amino alkane thiols such as 2-aminoethane thiol; alkyl mercaptans such as tert-dodecyl mercaptan, and mixtures of C₁₀-C₁₁ tertiary mercaptans; mercaptocarboxylate esters of polyols such as ethylene glycol bis (thioglycolate), ethylene glycol bis (mercatopropionate), trimethylolpropane tris (thioglycolate), trimethylolpropane tris(mercaptopropionate), pentaerythritol tetrakis(thioglycolate), pentaerythritol tetrakis(mercaptopropionate); thioglycolic acid, beta-mercaptoalanine, 2-mercaptobenzoic acid, 2-mercaptobenzothiazole, 2-mercaptobenzothiazyl disulfide, mercaptoethanol, beta-mercaptoethylamine hydrochloride, N-(2-mercaptoethyl)benzene sulfonamide, 2-mercapto-4-hydroxypyrimidine, 2-mercaptoimisazoline, mercaptomerin sodium, beta-mercaptopropionic acid, 6-mercaptopurine, mercapto succinic acid, and 2-mercaptothiazoline; aromatic sulfides such as diphenyl sulfide; and aromatic sulfoxides such as diphenyl sulfoxide and the like.

Examples of an inorganic “sulfur-containing” compound in an embodiment of the polishing composition include metal salts of acids such as thiosulfuric acid, disulfurous acid, polythionic acid, peroxodisulfuric acid and combinations thereof.

In an embodiment of the polishing composition, an organic additive is used up to about 10% by weight, based on the weight of the polishing composition. The organic additive functions as an encapsulating, suspending means for the abrasive particles, to minimize scratching associated with the hard abrasive particles and to improve the overall uniformity of the substrate surface. Alternatively, the organic additive improves the surface quality of the semiconductor substrate being polished by adsorbing onto the target metal layer as well as protecting the dielectric and associated barrier layer during the polishing process. Another use of the organic additive is to act as a pH buffer to stabilize the pH of the polishing composition. Exemplary organic additives contain hydroxy, carboxy, thiol, mercapto, amino groups and include compounds such as phthalates for e.g. ammonium hydrogen phthalate and potassium phthalate. Further, exemplary organic additives with carboxy moieties include organic acids with carboxylate, hydroxyl, sulfonic and phosphonic groups. Examples of organic acids are citric acid, lactic acid, malic acid and tartaric acid. The use of acid species for suppression of the rate of removal of the dielectric layer is described in detail in U.S. Pat. No. 5,476,606 which is herein incorporated by reference.

Uniform removal rates are a function of the pH of the polishing composition. Thus, a polishing composition with a stable pH is desired. In an embodiment, the polishing composition has a pH in a range of about 1.5 to 5 and contains abrasive particles made of alpha-alumina and gamma alumina. It is found that the time to attain a stable equilibrium pH value is a function of the weight percent of alpha-alumina and gamma-alumina in the abrasive. Thus, in polishing compositions containing alpha-alumina and gamma-alumina in the abrasive, pH stability is ensured by the addition of aluminum ions at molar concentrations up to 10 M. In an embodiment, dissolved aluminum(III) ions are provided at an initial concentration of 1M to obtain a polishing composition with a stable pH value of about 2. The molar concentration of dissolved aluminum ions at a particular pH is determined from solubility diagrams of alumina at various pH values illustrated in the FIG. 1. FIG. 1 is derived from FIG. 4, in the Aluminum Section of the Atlas of Electrochemical Equilibria, Marcel Pourbaix, 1966. In another embodiment, an organic acid such as citric acid is added in concentrations up to 2M to obtain a polishing composition with a stable pH. A stable pH as defined herein is a pH value that fluctuates by less than 0.5 pH units.

As discussed herein, various physical, chemical and mechanical parameters control the quality of the polished substrate surface. Polishing pressure or downforce controls the rate of polishing. A higher downforce results in a faster polishing rate while a lower downforce yields a polished surface of better quality since the abrasive particles do not scratch the substrate surface to the same extent as at higher downforce values. In CMP, the substrate (glass disk or semiconductor wafer) to be polished is mounted on a carrier or polishing head of the polishing apparatus. The exposed surface of the semiconductor substrate is placed against a rotating polishing pad. The surface of the polishing layer of the polishing pad that is in contact with the semiconductor device is referred to as the polishing layer. The polishing pad may be a known pad (without any abrasive in the polishing layer) also referred to herein as the non fixed-abrasive pad or a fixed-abrasive pad (containing abrasive in the polishing layer). The carrier head provides a controllable pressure (or downforce), on the substrate to push it against the polishing pad. A polishing composition with or without abrasive particles is then dispensed at the interface of the wafer and the polishing pad to enhance removal of the target layer (for e.g., metal in metal CMP processes). The polishing composition is typically water based and may or may not require the presence of abrasive particles, depending on the composition of the polishing layer of the polishing pad. An abrasive-free polishing fluid also referred to as a reactive liquid is typically used with a fixed-abrasive pad while a polishing fluid containing abrasive particles is typically used with a non fixed-abrasive pad. For polishing softer metal interconnects, such as copper, the polishing fluid can contain up to 3% by weight of abrasive particles. Typical abrasive particles that are used in CMP polishing of semiconductors are alumina, ceria, silica, titania, germania, diamond, silicon carbide, boron carbide, boron nitride, or combinations thereof. The polishing composition of this invention contains abrasive particles at about 0.5% to 55% by weight of the polishing composition.

Polishing is effected by lateral motion of the substrate relative to the polishing pad. The motion may be linear or circular or a combination thereof. The polishing pad surface has an initial micro-texture that is regenerated during polishing use of the pad by mechanical means for forming micro-texture, mounted on the polishing apparatus. The mechanical means is typically a 100-grit conditioning disk supplied by Abrasive Technology, Inc. The micro-texture reconditioning step is preferably performed at intervals during the polishing process, either during the step of applying the substrate against the pad, or more preferably during intervals when the substrate is disengaged from the pad. A suitable polishing apparatus equipped with a means for re-conditioning the pad surface (to regenerate micro-texture) is disclosed in U.S. Pat. No. 5,990,010. Polishing is terminated when the substrate achieves the desired degree of flatness with the metal layer being completely removed. An example of a polishing pad that may be used is a urethane polishing pad with a closed-cell structure.

### EXAMPLE 1

This example illustrates a significant improvement in the selectivity for platinum removal through the addition of thiosulfate ions to the polishing composition. The polishing experiment was performed on 200 mm wafers coated with platinum and silicon dioxide derived from TEOS using an IC1000-XY groove polishing pad, available from Rodel, Inc. (based in Newark, Del., USA), on a Strasbaugh 6DS-SP polishing machine. The IC1000-XY groove polishing pad was used along with a SUBA IV polishing pad as the sub-pad. SUBA IV polishing pads are also available from Rodel, Inc.

Polishing was performed under the following conditions:

| | | |
|---|---|---|
| Polishing downforce: | 4 | psi |
| Platen speed: | 80 | rpm |
| Carrier speed: | 60 | rpm |
| Back pressure: | 0 | psi |
| Slurry flow: | 200 | ml/min |
| Polishing Duration: | 60 | seconds. |

The IC1000-XY polishing pad was conditioned using two sweeps of a 4-inch, 100 grit diamond conditioner disc of the type available from Abrasive Technology, Inc. with constant flushing with deionized water. A platen speed of 50 rpm was utilized along with a downforce of 14 lbs during the conditioning cycle. The polished wafers were buffed utilizing a Politex pad and deionized water.

Different formulations of the polishing composition were prepared and used to polish the 200 mm wafers with platinum and silicon dioxide derived from TEOS. Table 1 presents platinum removal rate (RR) data and roughness values for the polished wafer surface for this experiment. All formulations of the polishing composition had a pH of 2. In addition, hydrochloric acid was added to each formulation at about 0.1% by weight of the formulation. The roughness values were measured using Digital Instruments Dimension 5000 Atomic Force Microsope utilizing a 20 micron by 20 micron scan area.

TABLE 1
Platinum Removal Rates (Å = Angstroms)

| | Alpha- | Citric | Sodium | | | | |
|---|---|---|---|---|---|---|---|
| | Alumina | Acid | Thiosulfate | Platinum RR | TEOS RR | Pt:TEOS | RMS |
| Slurry | wt % | (wt %) | (wt %) | (Å/min) | (Å/min) | Selectivity | (nm) |
| Baseline | 1.0 | 0.00 | 0.00 | 713 | 29 | 24.4 | 0.96 |
| A1 | 1.0 | 0.00 | 0.00 | 648 | 27 | 24.3 | 0.88 |
| B1 | 1.0 | 0.00 | 0.1 | 1296 | 55 | 23.7 | 0.78 |
| C1 | 1.0 | 0.00 | 0.3 | 1560 | 79 | 19.7 | 0.77 |
| D1 | 2.0 | 0.00 | 0.2 | 1661 | 108 | 15.4 | 1.06 |
| E1 | 3.0 | 0.00 | 0.1 | 1469 | 47 | 31.6 | 0.94 |
| F1 | 3.0 | 0.0 | 0.3 | 1726 | 61 | 28.2 | 0.67 |
| G1 | 1.0 | 0.2 | 0.2 | 1447 | 36 | 39.9 | 0.56 |
| H1 | 2.0 | 0.2 | 0.2 | 1555 | 51 | 30.3 | 0.7 |

As indicated by data in Table 1, for a fixed abrasive concentration, platinum removal rate is increased by the addition of thiosulfate ions. In addition, increasing the weight percent of alumina for a fixed concentration of thiosulfate ions increases the platinum removal rate. For a fixed abrasive concentration, adding citric acid improves the selectivity for platinum removal due to a decrease in oxide rate.

### EXAMPLE 2

200 mm wafers coated with platinum and silicon dioxide derived from TEOS were polished utilizing a Westech 372U polishing machine (available from IPEC/SPEEDFAM). All conditions were identical to those in Example 1, with the exception of downforce, which was changed to 4 psi. Different formulations of the polishing composition were prepared and used to polish the 200 mm wafers. Table 2 presents platinum removal rate data and roughness values for the polished wafer surface. All formulations of the polishing composition had a pH of 2. Surface Roughness values were measured using Digital Instruments Dimension 5000 Atomic Force Microsope utilizing a 20 micron by 20 micron scan area.

TABLE 2
Platinum Removal Rates
(HCl = hydrochloric acid; Pt = Platinum; Å = Angstroms)

| | Alpha- | Particle | | Citric | | | | |
|---|---|---|---|---|---|---|---|---|
| | Alumina | Size | HCl | Acid | Pt RR | TEOS RR in | Pt:TEOS | Ra |
| Slurry | wt % | (nm) | (wt %) | (wt %) | (Å/min) | (Å/min) | Selectivity | (nm) |
| A2 | 1.0 | 190 | 0.037 | 0.0 | 666 | 28 | 23.8 | 0.95 |
| B2 | 1.0 | 190 | 0.037 | 0.0 | 672 | 34 | 19.8 | 0.80 |
| C2 | 1.0 | 190 | 0.1 | 0.2 | 616 | 42 | 14.7 | 0.91 |
| D2 | 1.0 | 190 | 0.3 | 0.2 | 585 | 37 | 15.7 | 0.73 |
| E2 | 2.0 | 250 | 0.0 | 0.0 | 568 | 16 | 36.4 | 0.43 |
| F2 | 4.0 | 250 | 0.0 | 0.0 | 560 | 15 | 38.1 | 0.27 |

As may be seen from Table 2, the selectivity for platinum removal was enhanced through the addition of higher weight percentages of alumina for a given particle size.

### EXAMPLE 3

This example illustrates attainment of a stable pH value through the addition of aluminum ions and/or organic acids such as citric acid. A soluble aluminum salt such as aluminum chloride, aluminum citrate and/or aluminum nitrate can be used to provide aluminum ions. Aluminum chloride was used in this example. The following table illustrates the time to attain a stable pH (equilibrium) value in a range of about 3.7 to 4 for formulations of the polishing composition containing abrasives with varying weight percentages of alpha-alumina. The initial pH of each formulation of the polishing composition was 2.0 and the total abrasive concentration was held constant at 30 wt %.

TABLE 3
Time to attain a Stable pH

| | | Percent | |
|---|---|---|---|
| | Percent alpha- | gamma- | Time to Attain Stable pH |
| Sample No. | alumina | alumina | value (in days) |
| 1 | 0 | 100 | 1 |
| 2 | 75 | 25 | 9 |
| 3 | 99 | 1 | 37 |

A stable pH is obtained when a fixed dissolved concentration of Aluminum(III) (Al³⁺) ions is present in solution. The fixed dissolved Aluminum(III) concentration corresponds to the equilibrium concentration, for a specified pH value, based upon the solubility of hydrated alumina. Equilibrium Al(III) ion concentrations at a specific pH are obtained from a solubility diagram such as FIG. 1. As shown in FIG. 1, the final pH value in a range of about 3.7 to 4 corresponds to a dissolved aluminum concentration of 0.001M. Gamma-alumina dissolves faster than alpha-alumina, thus the time to attain a stable pH value is much shorter when the abrasive in the polishing composition contains only gamma-alumina. In contrast, the time to equilibrium when the abrasive comprises primarily alpha-alumina is much longer. By providing an initial fixed dissolved Aluminum(III) concentration in solution, a polishing composition with an immediately stable pH value is obtained.

Addition of an organic acid such as citric acid also stabilizes the pH of alumina slurries. Alumina particles dissolve until the dissolved aluminum (III) concentration in solution is the equilibrium value corresponding to a given pH value. The dissolution reaction causes hydroxyl ions to be released, according to the following reaction:

Al₂O₃+3H₂O=2Al³⁺+6OH⁻

When citric acid is present in the polishing composition in a proportionate amount, it complexes with the aluminum(III) ions. As a consequence of this complexation reaction, hydrogen ions are released, neutralizing the hydroxyl ions released by the above dissolution process, resulting in a stable pH.

What is claimed is:

1. An aqueous composition for chemical-mechanical polishing of a semiconductor substrate with a noble metal layer, a barrier layer, and a dielectric layer, said composition comprising:
abrasive particles present at a concentration from about 0.5% to about 55% by weight of said polishing composition;
an organic compound up to about 10% by weight of the polishing composition; and a ligand-containing compound at about 0.1% to about 50% by weight of the polishing composition, with said ligand having a stability constant with said noble metal in a range of about 5 to about 100;
said polishing composition providing a high selectivity between a metal layer and a dielectric layer or a metal layer and a barrier layer of a semiconductor device.

2. A composition according to claim 1 wherein said selectivity is in a range of about 1:1 to about 100:1.

3. A composition according to claim 2 wherein the ligand-containing compound is an inorganic sulfur-containing compound or an organic sulfur-containing compound.

4. A composition according to claim 3 wherein the sulfur-containing organic compound is selected from the group consisting of aromatic sulfide, aromatic sulfoxide, amino alkyl thiols, alkyl mercaptans, mercaptocarboxylate esters, thioglycolic acid, mercaptoalanines, mercaptoaromatic acids, mercaptoaromatic thiazoles, mercaptoaromatic thiazyl disulfides, mercaptoalkanols, mercaptoalkyl amine hydrochlorides, mercaptoalkyl aromatic sulfonamides, mercaptopropionic acid and mercapto succinic acid.

5. A composition according to claim 3 wherein the sulfur-containing inorganic compound is a metal salt of an acid selected from the group consisting of thiosulfuric acid, disulfurous acid, polythionic acid, peroxodisulfuric acid and combinations thereof.

6. A composition according to claim 5 wherein said abrasive is selected from the group consisting of alumina, ceria, silica, diamond, germania, zirconia, silicon carbide, boron nitride, boron carbide or combinations thereof.

7. A composition according to claim 6 wherein the organic compound has a moiety selected from the group consisting of hydroxy, carboxy, thiol, mercapto, and amino.

8. A composition according to claim 7 wherein said organic compound is an organic acid selected from the group consisting of dicarboxylic acids, tricarboxylic acids and hydroxy acids.

9. A composition according to claim 8 wherein said abrasive is alpha-alumina.

10. A composition according to claim 9 wherein the tricarboxylic acid is citric acid.

11. A composition according to claim 10 wherein the pH of the aqueous composition is in a range of about 1.5 to about 5.

12. A composition according to claim 11 wherein a stable pH value is attained by the addition of aluminum (III) ions at a molar concentration up to about 10 M.

13. A composition according to claim 8 wherein the hydroxy acid is malic acid.

14. A composition according to claim 8 wherein the hydroxy acid is lactic acid.

15. A method of polishing a surface of a semiconductor substrate having a noble metal circuit comprising the steps of:
i. positioning said substrate in a polishing machine such that the substrate is fixedly attached to a carrier in said polishing machine;
ii. providing a polishing pad with a polishing layer having a polishing surface, fixedly attached to a platen in said polishing machine;
iii. contacting said substrate fixedly attached to the carrier and the polishing pad fixedly attached to the platen while maintaining a relative motion between the pad and the substrate under a fixed pressure or downforce; and
iv. dispensing an aqueous polishing composition onto the polishing pad at the interface of the substrate and the polishing surface of the polishing pad so that the moving pressurized contact of the substrate against the polishing pad results in a substantially planarized surface of the substrate; wherein the polishing composition is the polishing composition of claim 1.

16. A method according to claim 15 performed with the polishing composition is of claim 9.

17. A method according to claim 15 performed with the polishing composition is of claim 10.

18. A method according to claim 15 performed with the polishing composition is of claim 11.

19. A method according to claim 15 performed with the polishing composition is of claim 12.
